(19) United States
(12) Patent Application Publication
(10) Pub. No.: US 2026/0323948 A1
(43) Pub. Date: Oct. 15, 2026

(54) 3D FLASH MEMORY FOR IMPROVING INTERFERENCE BETWEEN MEMORY CELLS AND METHOD FOR MANUFACTURING THE SAME

(71) Applicant: IUCF-HYU (Industry-University Cooperation Foundation Hanyang University), Seoul (KR)

(72) Inventors: Yun Heub SONG, Seoul (KR); Changhan Kim, Seoul (KR)

(73) Assignee: IUCF-HYU (Industry-University Cooperation Foundation Hanyang University), Seoul (KR)

(21) Appl. No.: 19/644,921

(22) Filed: Apr. 10, 2026

(30) Foreign Application Priority Data
Apr. 15, 2025 (KR) 10-2025-0049129
Mar. 3, 2026 (KR) 10-2026-0037858

(51) Int. Cl. H10B 43/35; H10B 43/27; H10B 51/20; H10B 51/30

(52) U.S. Cl. CPC H10B 43/35; H10B 43/27; H10B 51/20; H10B 51/30

(57) ABSTRACT

A 3D flash memory for improving interference between memory cells and a method of manufacturing the same are disclosed. According to an embodiment, the 3D flash memory has a data storage pattern structure including a protruding region protruding in the horizontal direction corresponding to gate electrodes and a recessed region recessed in the horizontal direction corresponding to interlayer insulating layers.

### CROSS REFERENCE TO RELATED PATENT APPLICATION

This application claims the benefit of priority of both Korean Application No. 10-2025-0049129, filed on Apr. 15, 2025, and Korean Application No. 10-2026-0037858, filed on Mar. 3, 2026, each of which is hereby incorporated by reference in its entirety.

### TECHNICAL FIELD

The following embodiments relate to a 3D flash memory for improving interference phenomena between memory cells and a method for manufacturing the same.

### BACKGROUND ART

A flash memory device is an electrically erasable programmable read-only memory (EEPROM) in which data input and output are electrically controlled by Fowler-Nordheim (F-N) tunneling or hot electron injection so that electrical programming and erasing are enabled, and the flash memory device may be commonly used in computers, digital cameras, MP3 players, game systems, memory sticks, and the like.

In a flash memory device, in order to increase the integration density to meet consumer demand for high performance and low cost, a 3D structure in which memory cell transistors are arranged in a vertical direction to form a cell string has been proposed.

However, in such 3D flash memory devices, parasitic coupling or electrical interference may occur between memory cells adjacent in the vertical direction, which causes problems that may degrade operating characteristics of the memory cells and reduce data reliability.

Accordingly, a technology capable of alleviating or preventing interference between memory cells adjacent in the vertical direction and improving operating stability and reliability of a memory device is required.

### SUMMARY OF THE INVENTION

### Technical Problem

Embodiments propose a 3D flash memory having a structure configured to increase the length of a path through which charge influence is transferred between memory cells, and a method for manufacturing the same, so as to alleviate or prevent interference between memory cells adjacent in the vertical direction and improve operating stability and reliability of a memory device.

More specifically, embodiments propose a 3D flash memory having a data storage pattern including a protruding region protruding in a horizontal direction corresponding to the gate electrodes and a recessed region recessed in the horizontal direction corresponding to the interlayer insulating layers, and a method for manufacturing the same, so as to increase the length of a path through which charge influence is transferred between memory cells.

The technical problems to be solved by the present invention are not limited to the above-described problems, and may be extended in various ways without departing from the technical idea and scope of the present invention.

### Solution to Problem

According to an embodiment, a 3D flash memory may include interlayer insulating layers and gate electrodes extending in a horizontal direction and alternately stacked in a vertical direction; and vertical channel structures extending in the vertical direction in channel holes penetrating the interlayer insulating layers and the gate electrodes, each of the vertical channel structures including a vertical channel pattern extending in the vertical direction, and a data storage pattern contacting an outer sidewall of the vertical channel pattern and extending in the vertical direction, the data storage pattern including a protruding region protruding in the horizontal direction corresponding to the gate electrodes and a recessed region recessed in the horizontal direction corresponding to the interlayer insulating layers.

According to one aspect, the data storage pattern may have a protruding and recessed profile in the horizontal direction, including the protruding region formed in spaces from which portions of the gate electrodes at inner sidewalls of each of the channel holes have been removed in the horizontal direction, and the recessed region recessed by a spacer film selectively deposited on inner sidewalls of the interlayer insulating layers in each of the channel holes.

According to another aspect, a horizontal distance from a central axis of the vertical channel pattern to the outer surface of the data storage pattern may vary along the vertical direction depending on the protruding region and the recessed region.

According to another aspect, the protruding region and the recessed region may be alternately arranged along the vertical direction.

According to another aspect, the vertical channel pattern may have a protruding and recessed profile in the horizontal direction corresponding to the protruding region and the recessed region of the data storage pattern.

According to another aspect, a protruding portion of the protruding and recessed profile of the vertical channel pattern may have a tapered shape having a width decreasing along the horizontal direction.

According to another aspect, the thickness of the data storage pattern may be different between the protruding region and the recessed region.

According to an embodiment, a method for manufacturing a 3D flash memory may include providing a semiconductor structure including sacrificial layers and interlayer insulating layers extending in a horizontal direction and alternately stacked in a vertical direction; forming channel holes penetrating the semiconductor structure in the vertical direction; selectively depositing a spacer film on regions of inner sidewalls of each of the channel holes corresponding to the interlayer insulating layers; removing, in the horizontal direction, portions of the sacrificial layers at inner sidewalls of each of the channel holes in which the spacer film has been selectively deposited; forming a data storage pattern extending in the vertical direction, the data storage pattern including a protruding region formed in spaces from which portions of the sacrificial layers have been removed and protruding in the horizontal direction, and a recessed region recessed in the horizontal direction at inner sidewalls of each of the channel holes in which the spacer film has been selectively deposited; forming a vertical channel pattern extending in the vertical direction on inner sidewalls of each of the channel holes in which the data storage pattern has been formed; and removing the sacrificial layers and forming gate electrodes in spaces from which the sacrificial layers have been removed.

According to one aspect, forming the data storage pattern extending in the vertical direction may include forming the data storage pattern having a protruding and recessed profile in the horizontal direction, wherein the protruding region is formed in spaces from which portions of the sacrificial layers have been removed in the horizontal direction, and the recessed region is recessed by the spacer film.

According to an embodiment, a method for manufacturing a 3D flash memory may include providing a semiconductor structure including gate electrodes and interlayer insulating layers extending in a horizontal direction and alternately stacked in a vertical direction; forming channel holes penetrating the semiconductor structure in the vertical direction; selectively depositing a spacer film on regions of inner sidewalls of each of the channel holes corresponding to the interlayer insulating layers; removing, in the horizontal direction, portions of the gate electrodes at inner sidewalls of each of the channel holes in which the spacer film has been selectively deposited; forming a data storage pattern extending in the vertical direction, the data storage pattern including a protruding region formed in spaces from which portions of the gate electrodes have been removed and protruding in the horizontal direction, and a recessed region recessed in the horizontal direction at inner sidewalls of each of the channel holes in which the spacer film has been selectively deposited; and forming a vertical channel pattern extending in the vertical direction on inner sidewalls of each of the channel holes in which the data storage pattern has been formed.

According to one aspect, forming the data storage pattern extending in the vertical direction may include forming the data storage pattern having a protruding and recessed profile in the horizontal direction, wherein the protruding region is formed in spaces from which portions of the gate electrodes have been removed in the horizontal direction, and the recessed region is recessed by the spacer film.

According to another aspect, forming the vertical channel pattern extending in the vertical direction may include forming the vertical channel pattern having a protruding and recessed profile in the horizontal direction corresponding to the protruding region and the recessed region of the data storage pattern.

### Advantageous Effects

The embodiments propose a 3D flash memory having a structure configured to increase the length of a path through which charge influence is transferred between memory cells, and a method for manufacturing the same, thereby alleviating or preventing interference between memory cells adjacent in the vertical direction and improving operating stability and reliability of a memory device.

More specifically, the embodiments may propose a 3D flash memory having a data storage pattern including a protruding region protruding in a horizontal direction corresponding to the gate electrodes and a recessed region recessed in the horizontal direction corresponding to the interlayer insulating layers, and a method for manufacturing the same, thereby providing a structure in which the length of a path through which charge influence is transferred between memory cells is increased.

However, the effects of the present invention are not limited to the above effects, and may be extended in various ways without departing from the technical idea and scope of the present invention.

### BRIEF DESCRIPTION OF DRAWINGS

FIG. 1 is a cross-sectional view illustrating a structure of a 3D flash memory according to an embodiment.

FIG. 2 is an enlarged cross-sectional view of a portion of the 3D flash memory shown in FIG. 1, to illustrate a structure in which the length of a path through which charge influence is transferred between memory cells is increased, according to an embodiment.

FIG. 3 is a cross-sectional view illustrating a structure of a 3D flash memory according to another embodiment.

FIG. 4 is an enlarged cross-sectional view of a portion of the 3D flash memory shown in FIG. 3, to illustrate a structure in which the length of a path through which charge influence is transferred between memory cells is increased, according to an embodiment.

FIG. 5 is a flowchart illustrating a method for manufacturing a 3D flash memory according to an embodiment.

FIGS. 6A to 6G are cross-sectional views illustrating structures of the 3D flash memory for describing the method for manufacturing the 3D flash memory shown in FIG. 5.

FIG. 7 is a flowchart illustrating a method for manufacturing a 3D flash memory according to another embodiment.

FIGS. 8A to 8E are cross-sectional views illustrating structures of the 3D flash memory for describing the method for manufacturing the 3D flash memory shown in FIG. 7.

### DETAILED DESCRIPTION

Hereinafter, embodiments of the present invention will be described in detail with reference to the accompanying drawings. However, the present invention is not limited by the embodiments. In addition, the same reference numerals shown in each drawing represent the same elements.

In addition, the terminology used in the present specification is used to appropriately express preferred embodiments of the present invention, and may vary depending on the intention of a viewer or an operator, or the convention in the field to which the present invention pertains. Therefore, definitions of these terms should be understood based on the overall contents of the present specification. For example, in the present specification, the singular form also includes the plural form unless otherwise specifically stated. In addition, “comprises” and/or “comprising” used in the present specification do not exclude the presence or addition of one or more other components, steps, operations and/or elements in addition to the recited components, steps, operations and/or elements. In addition, although terms such as first and second are used herein to describe various regions, directions, shapes, and the like, these regions, directions, and shapes should not be limited by these terms. These terms are merely used to distinguish one region, direction, or shape from another region, direction, or shape. Therefore, a portion referred to as a first portion in one embodiment may be referred to as a second portion in another embodiment.

It should also be understood that various embodiments of the present invention differ from each other but need not be mutually exclusive. For example, specific shapes, structures, and characteristics described herein with reference to one embodiment may be implemented in other embodiments without departing from the technical idea and scope of the present invention. It should also be understood that the positions, arrangements, or configurations of individual components in each of the presented embodiment categories may be changed without departing from the technical idea and scope of the present invention.

Hereinafter, with reference to the drawings, a 3D flash memory having a structure configured to increase the length of a path through which charge influence is transferred between memory cells, and a method for manufacturing the same, will be described in detail, so as to alleviate or prevent interference between memory cells adjacent in the vertical direction and improve operating stability and reliability of a memory device.

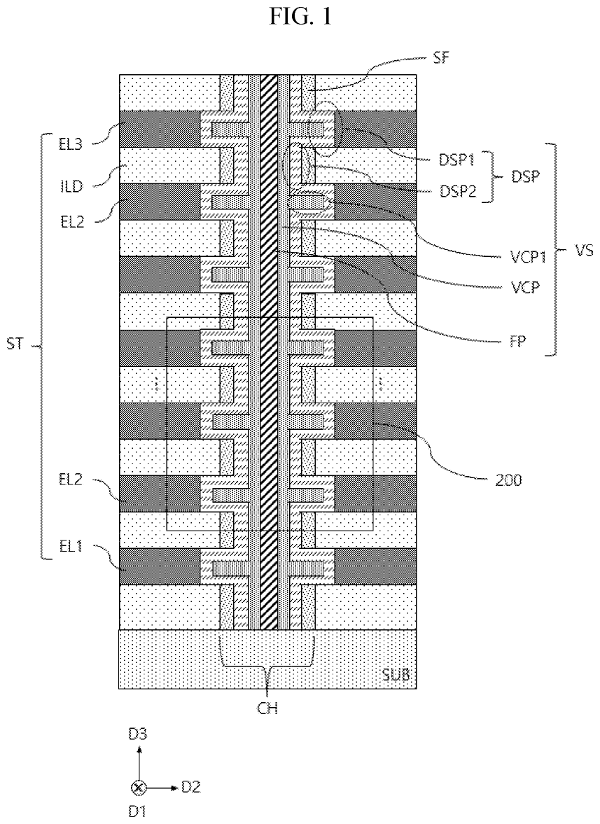

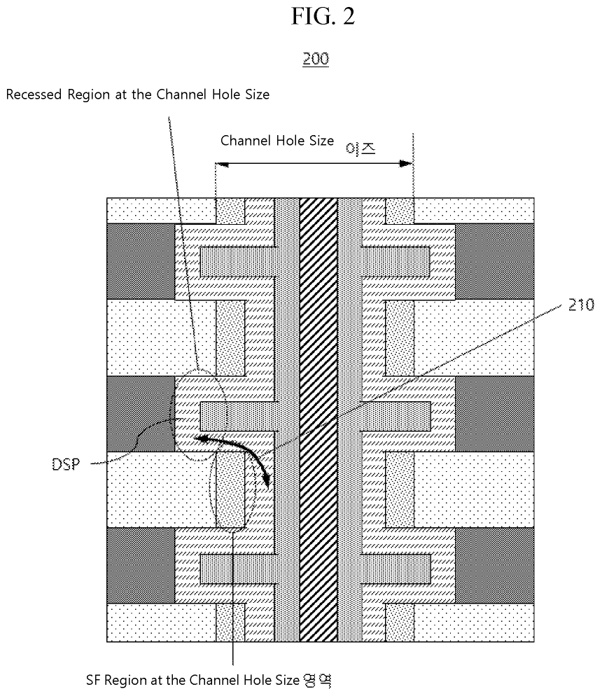

FIG. 1 is a cross-sectional view illustrating a structure of a 3D flash memory according to an embodiment, and FIG. 2 is an enlarged cross-sectional view of a portion of the 3D flash memory shown in FIG. 1, to illustrate a structure in which the length of a path through which charge influence is transferred between memory cells is increased, according to an embodiment.

Referring to FIG. 1, the substrate (SUB) may be a semiconductor substrate, such as a silicon substrate, a silicon-germanium substrate, a germanium substrate, or a monocrystalline epitaxial layer grown on a monocrystalline silicon substrate. The substrate (SUB) may be doped with first conductivity-type impurities (for example, P-type impurities).

Stacked structures (ST) may be disposed on the substrate (SUB). The stacked structures (ST) may be arranged two-dimensionally along a second direction (D2) while extending in a first direction (D1). In addition, the stacked structures (ST) may be spaced apart from each other in the second direction (D2).

Each of the stacked structures (ST) may include gate electrodes (EL1, EL2, EL3) and interlayer insulating layers (ILD) alternately stacked in a vertical direction (for example, the third direction (D3)) perpendicular to an upper surface of the substrate (SUB). The stacked structures (ST) may have substantially flat upper surfaces. That is, the upper surfaces of the stacked structures (ST) may be parallel to the upper surface of the substrate (SUB). Hereinafter, the vertical direction refers to the third direction (D3) or a direction opposite to the third direction (D3).

Each of the gate electrodes (EL1, EL2, EL3) may be one of an erase control line, ground select lines, word lines, and string select lines, which are sequentially stacked on the substrate (SUB).

Each of the gate electrodes (EL1, EL2, EL3) may be formed to extend in the first direction (D1) and may have substantially the same thickness in the third direction (D3). Hereinafter, the thickness refers to the thickness in the third direction (D3). Each of the gate electrodes (EL1, EL2, EL3) may be formed of a conductive material. For example, each of the gate electrodes (EL1, EL2, EL3) may include at least one selected from a doped semiconductor (for example, doped silicon, etc.), a metal (for example, tungsten (W), copper (Cu), aluminum (Al), titanium (Ti), tantalum (Ta), molybdenum (Mo), ruthenium (Ru), gold (Au), etc.), and a conductive metal nitride (for example, titanium nitride, tantalum nitride, etc.). Each of the gate electrodes (EL1, EL2, EL3) may further include at least one of all metal materials formable by ALD, in addition to the above-described metal materials.

More specifically, the gate electrodes (EL1, EL2, EL3) may include a lowermost first gate electrode (EL1), an uppermost third gate electrode (EL3), and a plurality of second gate electrodes (EL2) between the first gate electrode (EL1) and the third gate electrode (EL3). The first gate electrode (EL1) and the third gate electrode (EL3) are illustrated and described in the singular, but this is merely exemplary and not limiting, and the first gate electrode (EL1) and the third gate electrode (EL3) may each be provided in plurality. The first gate electrode (EL1) may correspond to ground select lines. The second gate electrode (EL2) may correspond to word lines. The third gate electrode (EL3) may correspond to string select lines.

Although not shown, an end portion of each of the stacked structures (ST) may have a stepwise structure along the first direction (D1). More specifically, the gate electrodes (EL1, EL2, EL3) of the stacked structures (ST) may have lengths in the first direction (D1) that decrease as they become farther from the substrate (SUB). The third gate electrode (EL3) may have the smallest length in the first direction (D1) and may have the greatest separation distance from the substrate (SUB) in the third direction (D3). The first gate electrode (EL1) may have the largest length in the first direction (D1) and may have the smallest separation distance from the substrate (SUB) in the third direction (D3). Due to the stepwise structure, each of the stacked structures (ST) may decrease in thickness as it becomes farther from the outermost one of vertical channel structures (VS) described below, and sidewalls of the gate electrodes (EL1, EL2, EL3) may be spaced apart at regular intervals along the first direction (D1) in a planar view.

Each of the interlayer insulating layers (ILD) may have different thicknesses. For example, the lowermost and uppermost ones of the interlayer insulating layers (ILD) may have a smaller thickness than the other interlayer insulating layers (ILD). However, this is only illustrative and not limiting, and the thicknesses of the interlayer insulating layers (ILD) may be different from each other or may all be set to have the same thickness, depending on the characteristics of the semiconductor device. The interlayer insulating layers (ILD) may be formed of an insulating material to electrically insulate the gate electrodes (EL1, EL2, EL3) from each other. For example, the interlayer insulating layers (ILD) may be formed of silicon oxide.

A plurality of channel holes (CH) may be provided through the stacked structures (ST) and a portion of the substrate (SUB). Vertical channel structures (VS) may be provided in the channel holes (CH). The vertical channel structures (VS) are cell strings (CSTR) and may extend in the third direction (D3) while being connected to the substrate (SUB). Connection of the vertical channel structures (VS) to the substrate (SUB) may be achieved by lower surfaces of the vertical channel structures (VS) abutting against the upper surface of the substrate (SUB), but is not limited thereto, and may also be achieved by a portion of each of the vertical channel structures (VS) being embedded within the substrate (SUB). When a portion of each of the vertical channel structures (VS) is embedded within the substrate (SUB), a lower surface of each of the vertical channel structures (VS) may be located at a lower level than the upper surface of the substrate (SUB).

A plurality of columns of vertical channel structures (VS) may be provided to penetrate one of the stacked structures (ST). For example, two columns of vertical channel structures (VS) may penetrate one of the stacked structures (ST). However, the present invention is not limited thereto, and three or more columns of vertical channel structures (VS) may penetrate one of the stacked structures (ST). In a pair of adjacent columns, the vertical channel structures (VS) corresponding to one column may be shifted in the first direction (D1) from the vertical channel structures (VS) corresponding to the other adjacent column. In a planar view, the vertical channel structures (VS) may be arranged in a zigzag shape along the first direction (D1). However, the present invention is not limited thereto, and the vertical channel structures (VS) may also form an arrangement in which the vertical channel structures (VS) are arranged side by side in rows and columns.

Each of the vertical channel structures (VS) may extend from the substrate (SUB) in the third direction (D3). Although each of the vertical channel structures (VS) is shown in the drawings to have a columnar shape with the same width at the top and the bottom, without being limited thereto, it may have a shape in which widths in the first direction (D1) and the second direction (D2) increase toward the third direction (D3). This is due to a limitation in that, when the channel holes (CH) are etched, the widths in the first direction (D1) and the second direction (D2) decrease toward a direction opposite to the third direction (D3). An upper surface of each of the vertical channel structures (VS) may have a circular shape, an elliptical shape, a rectangular shape, or a bar shape.

Each of the vertical channel structures (VS) may include a data storage pattern (DSP), a vertical channel pattern (VCP), a vertical filling pattern (FP), and a conductive pad (not shown). The vertical channel pattern (VCP) in each of the vertical channel structures (VS) may have a closed-bottom pipe shape or a macaroni shape. The vertical filling pattern (FP) may fill a space surrounded by the vertical channel pattern (VCP) and the conductive pad.

The data storage pattern (DSP) may cover inner sidewalls of each of the channel holes (CH), may surround an outer sidewall of the vertical channel pattern (VCP) on an inner side, and may contact sidewalls of the gate electrodes (EL) on an outer side. Thus, regions of the data storage pattern (DSP) corresponding to the second gate electrodes (EL2) may, together with regions of the vertical channel pattern (VCP) corresponding to the second gate electrodes (EL2), constitute memory cells in which memory operations (program operations, read operations, or erase operations) are performed by a voltage applied through the second gate electrodes (EL2). The memory cells correspond to memory cell transistors (MCT).

To this end, the data storage pattern (DSP) may trap charges or holes due to a voltage applied through the second gate electrodes (EL2), or may serve as a data storage medium in a 3D vertical structure memory by maintaining charge states (for example, polarization states of the charges). For example, an ONO (tunnel oxide-charge storage nitride-blocking oxide) layer or a ferroelectric layer may be used as the data storage pattern (DSP). Such a data storage pattern (DSP) may represent a binary data value or a multi-level data value according to a change in trapped charges or holes, or may represent a binary data value or a multi-level data value according to a change in charge states.

In particular, the data storage pattern (DSP) may include a protruding region (DSP1) protruding in the horizontal direction (for example, the first direction (D1) and the second direction (D2)) corresponding to the gate electrodes (EL), and a recessed region (DSP2) recessed in the horizontal direction (for example, the first direction (D1) and the second direction (D2)) corresponding to the interlayer insulating layers (ILD), to implement a structure configured to increase the length of a path through which charge influence is transferred between memory cells.

Hereinafter, protruding in the horizontal direction (for example, the first direction (D1) and the second direction (D2)) may mean being formed to extend in an outward direction with reference to a side surface of a reference structure.

In addition, recessing in the horizontal direction (for example, the first direction (D1) and the second direction (D2)) may mean being formed to recede in an inward direction with reference to a side surface of a reference structure.

More specifically, the protruding region (DSP1) may be formed in spaces from which portions of the gate electrodes (EL) at each inner sidewall have been removed in the horizontal direction (for example, the first direction (D1) and the second direction (D2)) during a manufacturing process, and the recessed region (DSP2) may be formed at a relatively recessed position (a retracted position) by a spacer film (SF) deposited on an inner sidewall of each of the interlayer insulating layers (ILD) during the manufacturing process.

Accordingly, the horizontal distance from the central axis of the vertical channel pattern (VCP) to the outer surface of the data storage pattern (DSP) may be formed differently along the vertical direction (for example, the third direction (D3)) depending on the protruding region (DSP1) and the recessed region (DSP2) that are alternately arranged along the vertical direction (for example, the third direction (D3)), through which the data storage pattern (DSP) may have a protruding and recessed profile in the horizontal direction (for example, the first direction (D1) and the second direction (D2)).

Due to such a structure, when a charge trapped in the protruding region (DSP1) at a position corresponding to the gate electrode (EL) transfers charge influence along the vertical direction (for example, the third direction (D3)) to a region of the data storage pattern (DSP) corresponding to another adjacent gate electrode (EL), the charge influence may be transferred through a path (210) extending along the recessed region (DSP2) of the data storage pattern (DSP), as shown in FIG. 2.

The described path (210) forms a significantly longer charge influence transfer path than in a conventional structure in which the protruding region (DSP1) and the recessed region (DSP2) are not formed, whereby the degree to which charge influence is transferred between memory cells adjacent in the vertical direction may be reduced.

Therefore, parasitic coupling or electrical interference between memory cells adjacent in the vertical direction may be effectively alleviated, resulting in improved operational stability and data reliability of a memory device.

In addition, the thickness of the data storage pattern (DSP) may have the same value in the protruding region (DSP1) and the recessed region (DSP2). This is because the vertical channel pattern (VCP) also has a protruding and recessed profile in the horizontal direction (for example, the first direction (D1) and the second direction (D2)) corresponding to the protruding region (DSP1) and the recessed region (DSP2) of the data storage pattern (DSP), while the shape of the protruding portion (VCP1) of the vertical channel pattern (VCP) is formed to be substantially the same as the shape of the protruding region (DSP1) of the data storage pattern (DSP).

As described above, the uniform thickness of the data storage pattern (DSP) may prevent thickness variations depending on positions in the vertical direction (for example, the third direction (D3)) of the data storage pattern (DSP) and ensure structural continuity, thereby improving step coverage and shape reproducibility in a deposition process for the data storage pattern (DSP), and preventing the occurrence of structurally weak portions due to local thickness reductions.

The vertical channel pattern (VCP) may be in contact with the inner sidewall of the tunneling film (TP) and may extend through the gate electrodes (EL1, EL2, EL3) in the vertical direction (for example, the third direction (D3)).

The vertical channel pattern (VCP), as a component that transfers charges or holes to the data storage pattern (DSP), may be formed of single-crystalline silicon or polysilicon so as to form a channel or be boosted by an applied voltage. However, the vertical channel pattern (VCP) is not limited thereto and may be formed of an oxide semiconductor material capable of blocking, suppressing, or minimizing leakage current. For example, the vertical channel pattern (VCP) may be formed of an oxide semiconductor material including at least one of In, Zn, and Ga and having excellent leakage current characteristics, or a group IV semiconductor material. The vertical channel pattern (VCP) may be formed of a ZnOx-based material including, for example, AZO, ZTO, IZO, ITO, IGZO, or Ag-ZnO. Thus, the vertical channel pattern (VCP) can block, suppress, or minimize leakage current to the gate electrodes (EL1, EL2, EL3) or the substrate (SUB), and can improve transistor characteristics (for example, threshold voltage distribution and speeds of program/read operations) of at least one of the gate electrodes (EL1, EL2, EL3), thereby improving electrical characteristics of the 3D flash memory.

The lower surface of the vertical channel pattern (VCP) may be in contact with the substrate (SUB), and the upper surface of the vertical channel pattern (VCP) may be located at a higher level than the upper surface of the third gate electrode (EL3), and may be substantially coplanar with the upper surface of the vertical filling pattern (FP) and be in contact with the lower surface of the conductive pad.

The vertical channel pattern (VCP) may be provided between the data storage pattern (DSP) and the vertical filling pattern (FP), and may correspond to the second gate electrodes (EL2). Thus, the vertical channel pattern (VCP) may constitute memory cells together with the data storage pattern (DSP), as described above.

In particular, the vertical channel pattern (VCP) may have a protruding and recessed profile in the horizontal direction (for example, the first direction (D1) and the second direction (D2)) corresponding to the protruding region (DSP1) and the recessed region (DSP2) of the data storage pattern (DSP).

Herein, that the vertical channel pattern (VCP) has a protruding and recessed profile in the horizontal direction (for example, the first direction (D1) and the second direction (D2)) corresponding to the protruding region (DSP1) and the recessed region (DSP2) of the data storage pattern (DSP) may mean that, while an outer boundary of the vertical channel pattern (VCP) extends along the vertical direction (for example, the third direction (D3)), a section corresponding to a vertical position at which the protruding region (DSP1) of the data storage pattern (DSP) is located protrudes relatively more in the horizontal direction, and a section corresponding to a vertical position at which the recessed region (DSP2) of the data storage pattern (DSP) is located is formed to protrude relatively less or be recessed.

As described above, the shape of the protruding portion (VCP1) of the vertical channel pattern (VCP) is formed to be substantially the same as the shape of the protruding region (DSP1) of the data storage pattern (DSP), thereby allowing the thickness of the data storage pattern (DSP) to have the same value in the protruding region (DSP1) and the recessed region (DSP2).

The vertical filling pattern (FP) may be surrounded by the vertical channel pattern (VCP). The upper surface of the vertical filling pattern (FP) may be in contact with the conductive pad, and the lower surface of the vertical filling pattern (FP) may be in contact with the upper surface of the lower inner end of the vertical channel pattern (VCP). The vertical filling pattern (FP) may be spaced apart from the substrate (SUB) in the third direction (D3). That is, the vertical filling pattern (FP) may be electrically floating with respect to the substrate (SUB).

The vertical filling pattern (FP) may be formed of a material that facilitates diffusion of charges or holes in the vertical channel pattern (VCP). In more detail, the vertical filling pattern (FP) may be formed of a material having excellent charge and hole mobility. For example, the vertical filling pattern (FP) may be formed of a semiconductor material doped with an impurity, an intrinsic semiconductor material in an undoped state, or a polycrystalline semiconductor material. In a more specific example, the vertical filling pattern (FP) may be formed of polysilicon doped with the same first conductivity-type impurity (for example, a P-type impurity) as that of the substrate (SUB). That is, the vertical filling pattern (FP) may improve electrical characteristics of the 3D flash memory, thereby improving memory operation speeds.

The vertical channel structures (VS) may correspond to channels of erase control transistors, string selection transistors, ground selection transistors, and memory cell transistors.

A conductive pad (not shown) may be provided on the upper surface of the vertical channel pattern (VCP) and the upper surface of the vertical filling pattern (FP). The conductive pad may be connected to an upper portion of the vertical channel pattern (VCP) and an upper portion of the vertical filling pattern (FP). The sidewall of the conductive pad may be surrounded by the data storage pattern (DSP). The upper surface of the conductive pad may be substantially coplanar with an upper surface of each of the stack structures (ST) (that is, an upper surface of a topmost one of the interlayer insulating layers (ILD)). The lower surface of the conductive pad may be located at a lower level than the upper surface of the third gate electrode (EL3). More specifically, the lower surface of the conductive pad may be located between the upper surface and the lower surface of the third gate electrode (EL3). That is, at least a part of the conductive pad may overlap the third gate electrode (EL3) in the horizontal direction.

The conductive pad may be formed of a semiconductor material doped with impurities or a conductive material. For example, the conductive pad may be formed of a semiconductor material doped with impurities different from those of the vertical filling pattern (FP) (more precisely, impurities of a second conductivity type (for example, N-type) different from those of a first conductivity type (for example, P-type)).

The conductive pad may reduce the contact resistance between a bit line (not shown) described below and the vertical channel pattern (VCP) (or the vertical filling pattern (FP)).

Although the vertical channel structures (VS) have been described above as having a structure including a conductive pad, the embodiment is not limited thereto, and they may have a structure in which the conductive pad is omitted. In this case, as the conductive pad is omitted from the vertical channel structures (VS), each of the vertical channel pattern (VCP) and the vertical filling pattern (FP) may extend in the third direction (D3) such that the upper surfaces of the vertical channel pattern (VCP) and the vertical filling pattern (FP) are substantially coplanar with the upper surface of each of the stack structures (ST) (that is, the upper surface of a topmost one of the interlayer insulating layers (ILD)). In addition, in this case, a bit line contact plug (not shown) described below may be in direct contact with and electrically connected to the vertical channel pattern (VCP), instead of being indirectly electrically connected to the vertical channel pattern (VCP) through a conductive pad.

In addition, although the vertical channel structures (VS) have been described above as including the vertical filling pattern (FP), the present invention is not limited thereto, and the vertical filling pattern (FP) may be omitted.

For example, although a 3D flash memory having a structure including the vertical filling pattern (FP) has been described, the 3D flash memory may have a structure including a back gate (not shown) while omitting the vertical filling pattern (FP).

In this regard, the back gate further included in each of the vertical channel structures (VS) may fill the internal space of the vertical channel pattern (VCP) and be formed to extend in the vertical direction (for example, the third direction (D3)). Hereinafter, that the back gate fills the internal space of the vertical channel pattern (VCP) means that the back gate is included within the vertical channel pattern (VCP) while being at least partially surrounded by the vertical channel pattern (VCP).

The back gate may abut the vertical channel pattern (VCP) while being at least partially surrounded by the vertical channel pattern (VCP), and may be formed to apply a voltage to the vertical channel pattern (VCP) for memory operation. To this end, the back gate may be formed of a conductive material including at least one selected from a doped semiconductor (for example, doped silicon, etc.), a metal (for example, tungsten (W), copper (Cu), aluminum (Al), titanium (Ti), tantalum (Ta), molybdenum (Mo), ruthenium (Ru), gold (Au), etc.), or a conductive metal nitride (for example, titanium nitride, tantalum nitride, etc.), etc. The back gate may include at least one of all metal materials formable by ALD, in addition to the metal materials described above.

In this case, the back gate may be formed to extend along the third direction (D3) from a level corresponding to the first gate electrode (EL1) to a level corresponding to the second gate electrode (EL2) within the vertical channel pattern (VCP). That is, the upper surface of the back gate may be located at a higher level than the upper surface of a topmost one of the second gate electrodes (EL2). However, the present invention is not limited thereto, and the back gate may also be formed to extend along the third direction (D3) to a level corresponding to the third gate electrode (EL3) within the vertical channel pattern (VCP).

Such a back gate is included in the vertical channel pattern (VCP) of each of the cell strings, and the back gate included in the vertical channel pattern (VCP) of each of the cell strings may all be electrically connected on a plane formed by the first direction (D1) and the second direction (D2). That is, the back gate may be commonly connected to the cell strings. In this case, each back gate of the cell strings may be collectively controlled such that the same voltage is applied to all of them.

However, the present invention is not limited thereto, and the back gate included in the vertical channel pattern (VCP) of each of the cell strings may be electrically connected to each other along the first direction (D1). In this case, the back gate of each of the cell strings arranged along the second direction (D2) may be independently controlled electrically such that different voltages may be applied thereto, and the back gate of each of the cell strings arranged along the first direction (D1) may be collectively controlled such that the same voltage may be applied thereto.

In addition, the back gate included in the vertical channel pattern (VCP) of each of the cell strings may be in an electrically separated state for each of the vertical channel structures (VS). In this case, the back gate of each of the vertical channel structures (VS) may all be individually controlled.

An insulating film (not shown) may be disposed between the back gate and the vertical channel pattern (VCP), thereby preventing the back gate from directly contacting the vertical channel pattern (VCP). Like the interlayer insulating layers (ILD), the insulating film may be formed of an insulating material such as silicon oxide.

A separation trench (not shown) extending in the first direction (D1) may be provided between the stack structures (ST) adjacent to each other. A common source region (not shown) may be provided in the substrate (SUB) exposed by the separation trench (TR). The common source region may extend in the first direction (D1) within the substrate (SUB). The common source region may be formed of a semiconductor material doped with an impurity of a second conductivity type (for example, an N-type impurity). The common source region may refer to a source line.

A common source plug (not shown) may be provided in the separation trench. The common source plug may be connected to the common source region, and an upper surface thereof may be substantially coplanar with an upper surface of each of the stack structures (ST) (that is, an upper surface of a topmost one of the interlayer insulating layers (ILD)). The common source plug may have a plate shape extending in the first direction (D1) and the third direction (D3). In this case, the common source plug may have a shape whose width in the second direction (D2) increases toward the third direction (D3).

Insulating spacers (not shown) may be interposed between the common source plug and the stack structures (ST). The insulating spacers may be provided to face each other between the stack structures (ST) adjacent to each other. For example, the insulating spacers may be formed of silicon oxide, silicon nitride, silicon oxynitride, or a low-k material having a low dielectric constant.

A capping insulating film (not shown) may be provided on the stack structures (ST), the vertical channel structures (VS), and the common source plug. The capping insulating film may cover an upper surface of a topmost one of the interlayer insulating layers (ILD), the upper surface of the conductive pad, and the upper surface of the common source plug. The capping insulating film may be formed of an insulating material different from that of the interlayer insulating layers (ILD). A bit line contact plug (not shown) electrically connected to the conductive pad may be provided inside the capping insulating film. The bit line contact plug (not shown) may have a shape whose widths in the first direction (D1) and the second direction (D2) increase toward the third direction (D3).

A bit line (not shown) may be provided on the capping insulating film and the bit line contact plug (not shown). The bit line may be formed of a conductive material to extend along the second direction (D2), and may be individually provided for the vertical channel structures (VS) so as to be configured in plurality. The conductive material forming the bit line may be the same material as that forming each of the gate electrodes (EL1, EL2, EL3) described above.

The bit line may be electrically connected to the vertical channel structures (VS) through a bit line contact plug. Herein, that the bit line is connected to the vertical channel structures (VS) may mean that the bit line is connected to the vertical channel pattern (VCP) included in the vertical channel structures (VS).

A 3D flash memory having such a structure may perform program, read, and erase operations based on voltages applied to each of the cell strings (CSTR), a voltage applied to the string select line, voltages applied to each of the word lines, a voltage applied to the ground select line, a voltage applied to the bit line, and a voltage applied to the source line (including a voltage applied to the back gate in a case of including the back gate). For example, the 3D flash memory may perform a program operation by forming a channel in the vertical channel pattern (VCP) and transferring charges or holes to the data storage pattern (DSP) of a target memory cell based on voltages applied to each of the cell strings, a voltage applied to the string select line, voltages applied to each of the word lines, a voltage applied to the ground select line, a voltage applied to the bit line, and a voltage applied to the source line (including a voltage applied to the back gate in a case of including the back gate).

A 3D flash memory according to an embodiment is not limited to the described structure, and may be implemented in various structures according to implementation examples, on the premise of including a data storage pattern (DSP) and a vertical channel pattern (VCP) that result in a structure configured to increase a length of a path through which the influence of charges is transferred between memory cells, as well as gate electrodes (EL1, EL2, EL3), the bit line, and the source line.

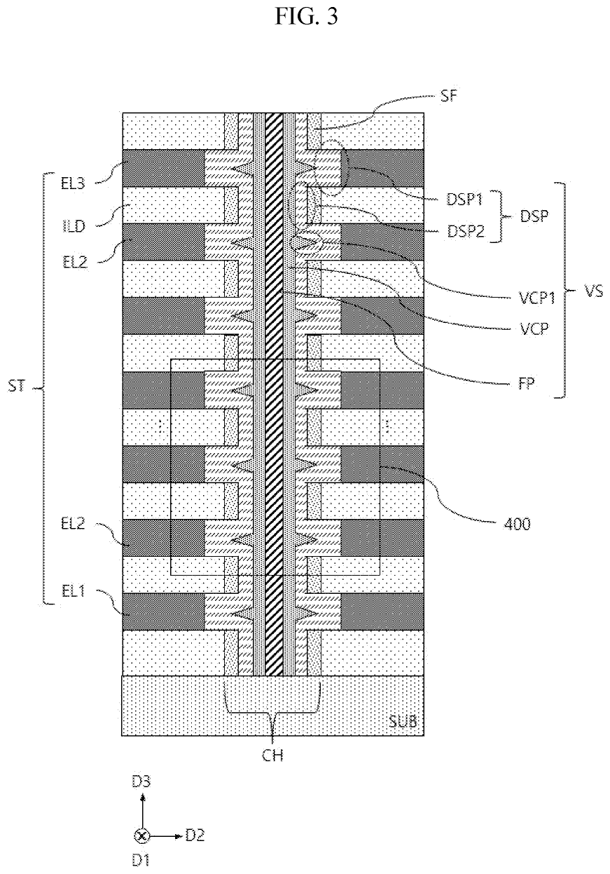

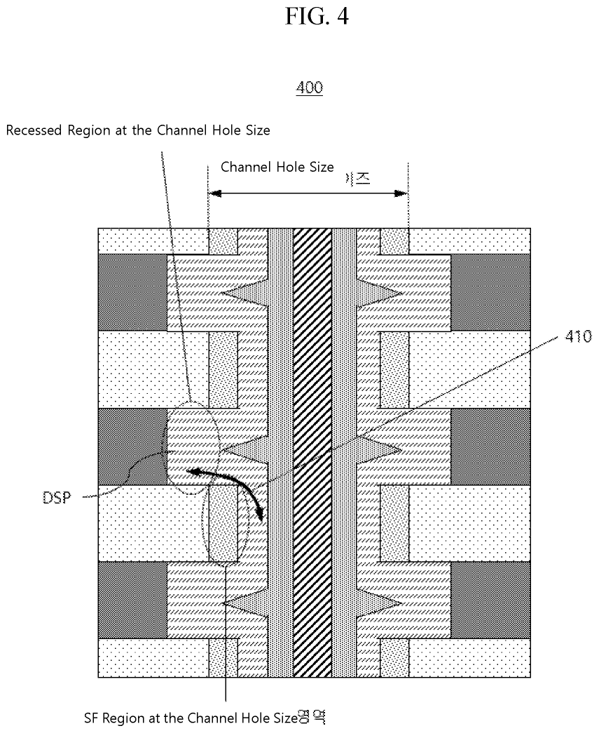

FIG. 3 is a cross-sectional view illustrating a structure of a 3D flash memory according to another embodiment, and FIG. 4 is an enlarged cross-sectional view of a portion of the 3D flash memory shown in FIG. 3, for describing a structure in which the length of a path through which charge influence is transferred between memory cells is increased according to an embodiment.

The 3D flash memory described below may have the same structure as that of the 3D flash memory described above with reference to FIG. 1, but it may have a differentiated structure in that a protruding portion (VCP1) of the vertical channel pattern (VCP) has a tapered shape.

Therefore, hereinafter, the description will focus on the shape of the protruding portion (VCP1) of the vertical channel pattern (VCP) and the structural features according thereto, and redundant descriptions for other components will be omitted.

Referring to FIG. 3, the protruding portion (VCP1) of the vertical channel pattern (VCP) may be formed in a tapered shape in which a protruding width in the horizontal direction (for example, the first direction (D1) and the second direction (D2)) gradually decreases along the vertical direction (for example, the third direction (D3)). For example, the protruding portion (VCP1) protrudes outward at a position corresponding to the protruding region (DSP1) of the data storage pattern (DSP), and as shown in the drawing, may have a shape including an inclined sidewall at an outer boundary and in which the protruding width gradually decreases along the vertical direction (for example, the third direction (D3)).

As such, in a case where the protruding portion (VCP1) of the vertical channel pattern (VCP) is formed in a tapered shape, the thickness of the data storage pattern (DSP) may have different values in the protruding region (DSP1) and the recessed region (DSP2).

For example, the data storage pattern (DSP) may be formed with a relatively large thickness in the protruding region (DSP1) corresponding to the protruding portion (VCP1) of the vertical channel pattern (VCP), and may be formed with a relatively small thickness at a position corresponding to the recessed region (DSP2). This is because, as the protruding portion (VCP1) of the vertical channel pattern (VCP) protrudes outward while having a tapered shape, an effective space in which the data storage pattern (DSP) is formed relatively increases in the protruding region (DSP1).

The recessed region (DSP2) of the data storage pattern (DSP) may correspond to an inactive region located between adjacent gate electrodes (EL), rather than an active region of a memory cell corresponding to the gate electrode (EL). Therefore, since a thickness change in the recessed region (DSP2) is not in a primary region in which charge traps occur, it may not directly affect charge trap characteristics, charge retention characteristics, and program and erase characteristics of the memory cell.

That is, as long as the thickness of the data storage pattern (DSP) is maintained at a thickness sufficient to stably perform a charge trapping function in the protruding region (DSP1) corresponding to the gate electrode (EL), a thickness change in the recessed region (DSP2) may be formed within a range that does not have a substantially effective influence on electrical operation characteristics of the memory cell.

Similarly, in the described structure, when a charge trapped in the protruding region (DSP1) at a location corresponding to the gate electrode (EL) transfers influence along the vertical direction (for example, the third direction (D3)) to a region of the data storage pattern (DSP) corresponding to another gate electrode (EL) adjacent thereto, the charge influence may be transferred through a path (410) extending along the recessed region (DSP2) of the data storage pattern (DSP), as shown in FIG. 4.

Such a path (410) forms a significantly longer charge influence transfer path compared to a conventional structure in which the protruding region (DSP1) and the recessed region (DSP2) are not formed, so that the degree to which charge influence is transferred between memory cells adjacent in the vertical direction may be reduced.

Meanwhile, as the protruding portion (VCP1) of the vertical channel pattern (VCP) has a tapered shape, control of process conditions of an etching process or a deposition process for forming the vertical channel pattern (VCP) may become relatively easier.

Specifically, as the protruding portion (VCP1) is gradually formed without a sharp change in shape, shape non-uniformity such as distortion of an etching profile, local over-etching, or under-etching during an etching process may be suppressed. In addition, even during a deposition process, step coverage of a material is improved, so that a more uniform shape may be ensured even in a high-aspect-ratio structure.

Furthermore, the tapered shape may reduce shape sensitivity due to changes in process conditions to improve shape reproducibility, and may improve stability of a process for forming the vertical channel pattern (VCP) and effectively reduce manufacturing process difficulty.

Accordingly, even when the protruding portion (VCP1) of the vertical channel pattern (VCP) is formed in a tapered shape, ease of the manufacturing process of the vertical channel pattern (VCP) may be improved while stability of electrical characteristics of a memory cell is maintained.

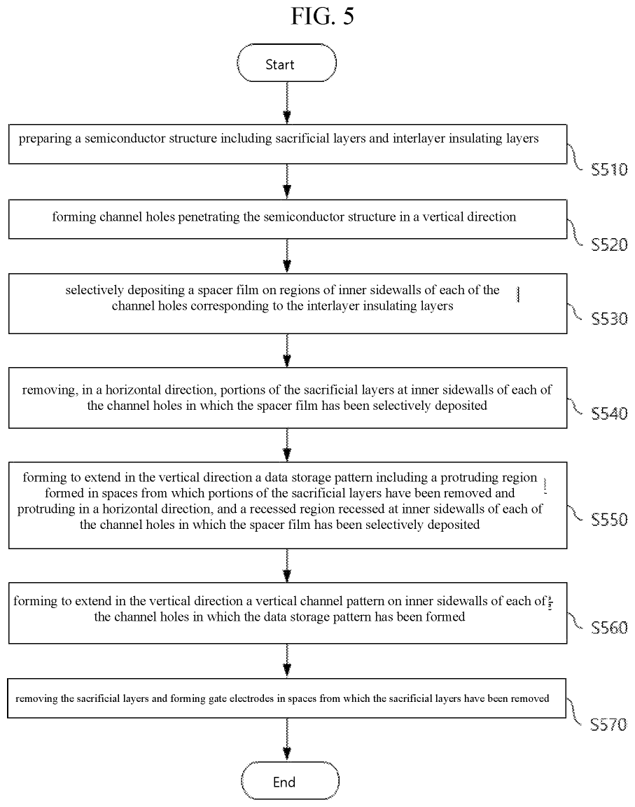

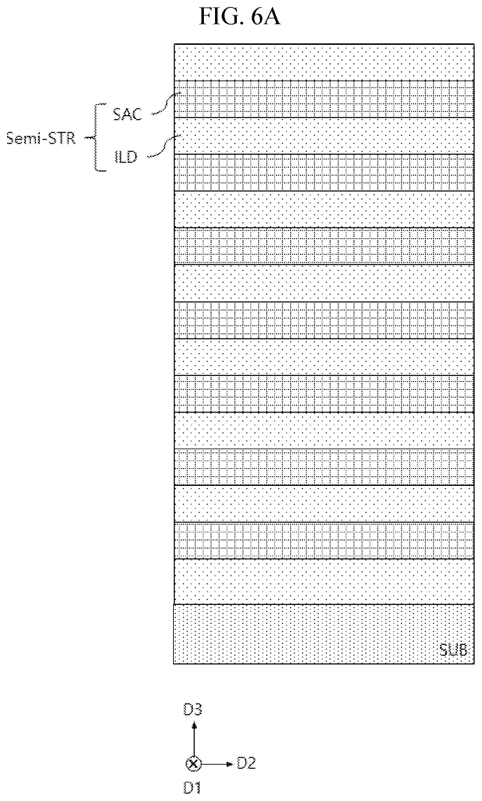

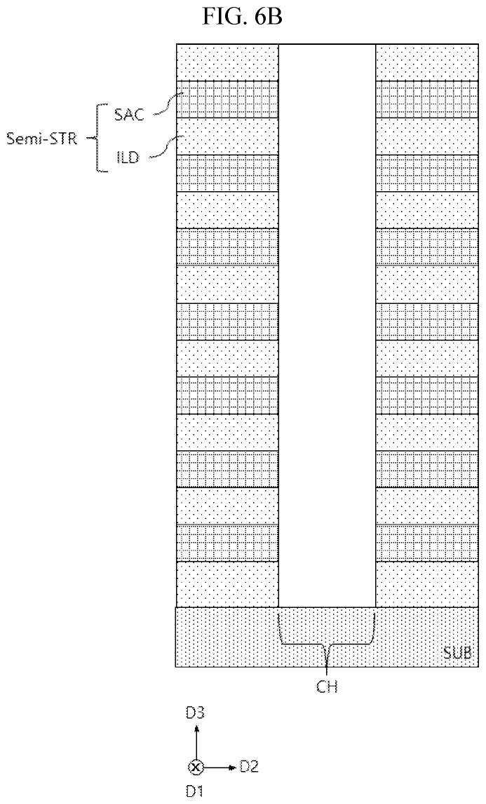

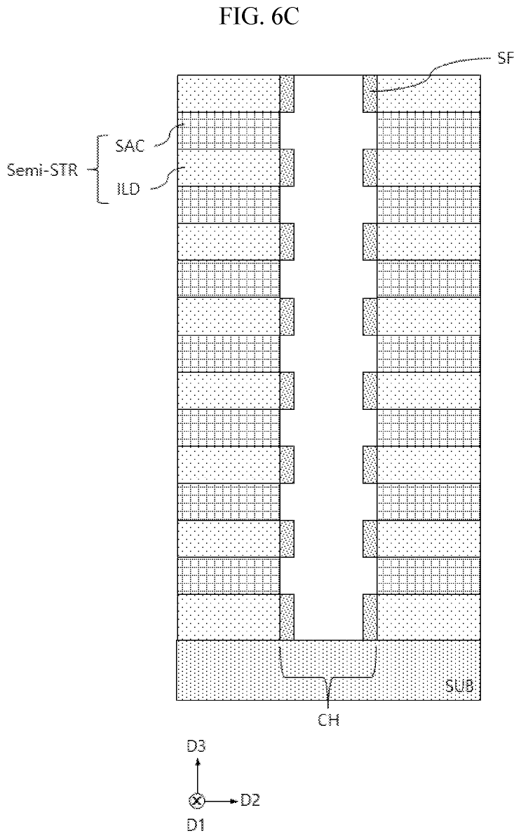

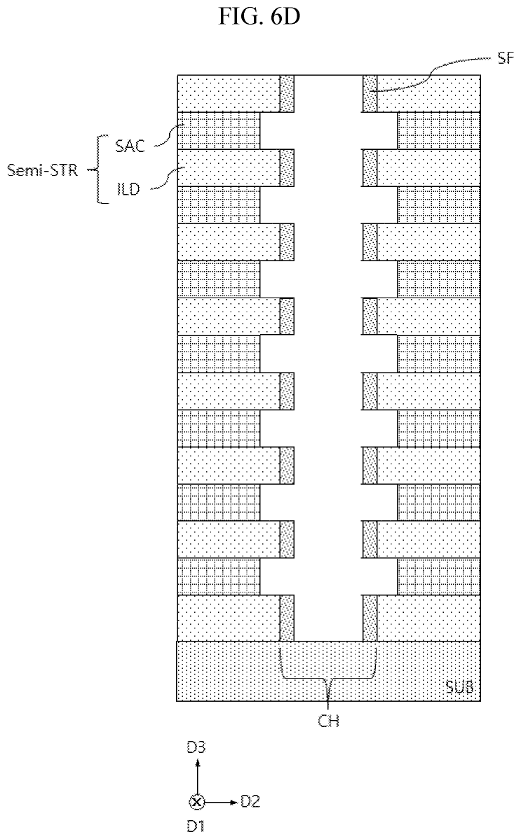

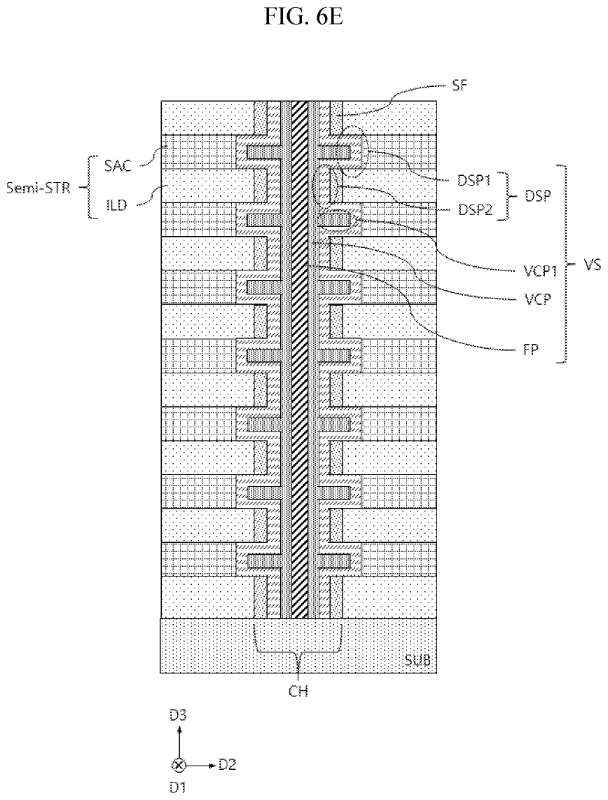

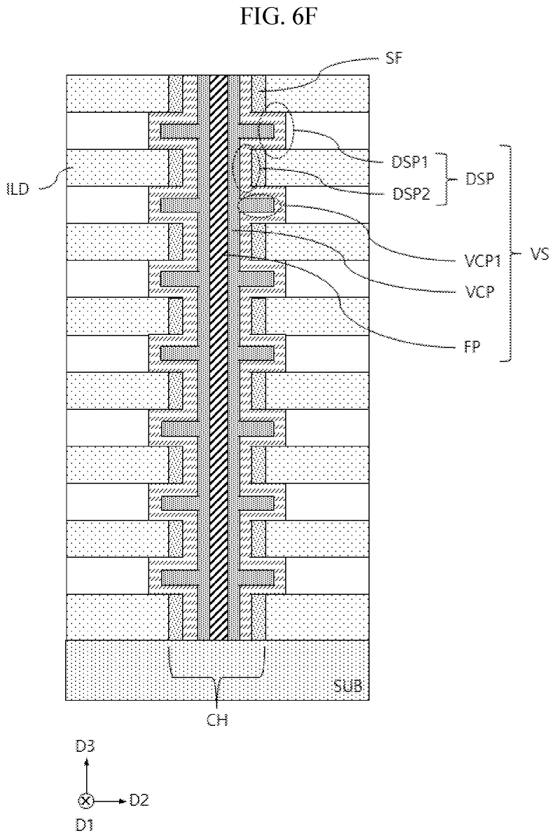

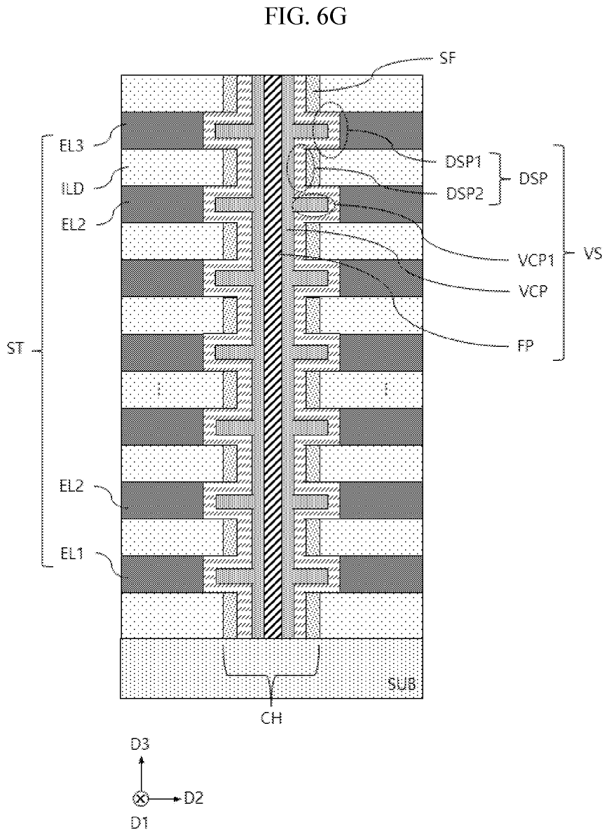

FIG. 5 is a flowchart illustrating a method for manufacturing a 3D flash memory according to an embodiment, and FIGS. 6A to 6G are cross-sectional views illustrating structures of a 3D flash memory for describing the method for manufacturing the 3D flash memory shown in FIG. 5.

The manufacturing method described below is for manufacturing a 3D flash memory having the structure shown in FIG. 1 based on a gate replacement technique, and is based on the premise that it is performed by an automated and mechanized manufacturing system.

However, the present invention is not limited thereto, and, in a 3D flash memory having the structure shown in FIG. 3, the overall order and method of the manufacturing process may also be applied in substantially the same manner, except that only the shape of the protruding portion (VCP1) of the vertical channel pattern (VCP) is different. That is, the manufacturing method described below may be applied in the same manner to manufacture a 3D flash memory not only when the protruding portion (VCP1) of the vertical channel pattern (VCP) is formed to have the same shape corresponding to the protruding region (DSP1) and the recessed region (DSP2) of the data storage pattern (DSP), but also when the protruding portion (VCP1) is formed to have a tapered shape whose protruding width gradually decreases along the vertical direction.

In this case, the protruding portion (VCP1) of the vertical channel pattern (VCP) may be selectively formed to have the same shape or a tapered shape by appropriately controlling process conditions for removing a portion of the data storage pattern (DSP) corresponding to the sacrificial layers (SAC) and process conditions for forming the vertical channel pattern (VCP) in spaces from which a portion of the data storage pattern (DSP) has been removed, so that a 3D flash memory including vertical channel patterns (VCP) of various shapes may be manufactured within the same process flow.

Therefore, the manufacturing method described below is not limited to a specific protruding shape of the vertical channel pattern (VCP), but may be commonly applied to the manufacture of a 3D flash memory including vertical channel patterns (VCP) having various protruding shapes.

Referring to FIG. 5, in step (S510), the manufacturing system may prepare a semiconductor structure (SEMI-STR) including sacrificial layers (SAC) and interlayer insulating layers (ILD) that are formed to extend in a horizontal direction (for example, the first direction (D1) and the second direction (D2)) and are alternately stacked in the vertical direction, as shown in FIG. 6A.

In step (S520), the manufacturing system may form channel holes (CH) penetrating the semiconductor structure (SEMI-STR) in the vertical direction, as shown in FIG. 6B. Various etching schemes may be used in step (S520) of forming the channel holes (CH).

In step (S530), the manufacturing system may selectively deposit a spacer film (SF) on regions of inner sidewalls of each of the channel holes (CH) corresponding to the interlayer insulating layers (ILD), as shown in FIG. 6C.

Selective deposition of the spacer film (SF) only in regions corresponding to the interlayer insulating layers (ILD) may be achieved by performing a deposition process in the channel holes (CH) after a process of activating surfaces of the interlayer insulating layers (ILD) exposed within the channel holes (CH) and deactivating surfaces of the sacrificial layers (SAC) exposed within the channel holes (CH).

As such, step (S530) of selectively depositing a spacer film (SF) in regions corresponding to the interlayer insulating layers (ILD) is to allow the recessed region (DSP2) of the data storage pattern (DSP) to be disposed at a relatively recessed position in step (S550) described below.

In step (S540), the manufacturing system, as shown in FIG. 6D, may remove portions of the sacrificial layers (SAC) from inner sidewalls of each of the channel holes (CH) in which the spacer film (SF) has been selectively deposited, in the horizontal direction (for example, the first direction (D1) and the second direction (D2)).

Step (S540) of removing portions of the sacrificial layers (SAC) is to secure a space in which the protruding region (DSP1) of the data storage pattern (DSP), corresponding to the sacrificial layers (SAC) (the gate electrodes (EL) to be formed in spaces from which the sacrificial layers (SAC) are removed), is formed.

In step (S550), the manufacturing system may form a data storage pattern (DSP) extending in the vertical direction (for example, the third direction (D3)) and including a protruding region (DSP1) formed in spaces from which portions of the sacrificial layers (SAC) have been removed and protruding in the horizontal direction (for example, the first direction (D1) and the second direction (D2)), and a recessed region (DSP2) recessed in the horizontal direction (for example, the first direction (D1) and the second direction (D2)) at inner sidewalls of each of the channel holes (CH) in which the spacer film (SF) has been selectively deposited.

Based on steps (S530 and S540), as the protruding region (DSP1) is formed in spaces from which portions of the sacrificial layers (SAC) have been removed in the horizontal direction (for example, the first direction (D1) and the second direction (D2)), and the recessed region (DSP2) is recessed by the spacer film (SF), step (S550) may be a step of forming the data storage pattern (DSP) having a protruding and recessed profile in the horizontal direction (for example, the first direction (D1) and the second direction (D2)).

Due to this structure, when a charge trapped in the protruding region (DSP1) at a position corresponding to the gate electrode (EL) transfers influence along the vertical direction (for example, the third direction (D3)) to a region of the data storage pattern (DSP) corresponding to another gate electrode (EL) adjacent thereto, the charge influence transfer path extends in a form including a path extending along the protruding region (DSP1) and the recessed region (DSP2), and thus may have a significantly increased length compared to a conventional structure in which the protruding region (DSP1) and the recessed region (DSP2) are not formed.

Therefore, parasitic coupling or electrical interference that may occur between memory cells adjacent in the vertical direction may be effectively alleviated, and as a result, operation stability and data reliability of a memory device may be improved.

In step (S560), the manufacturing system may form the vertical channel pattern (VCP) extending in the vertical direction (for example, the third direction (D3)) on inner sidewalls of each of the channel holes (CH) in which the data storage pattern (DSP) is formed.

At this time, the manufacturing system may also form the vertical channel pattern (VCP) to have a protruding and recessed profile in the horizontal direction (for example, the first direction (D1) and the second direction (D2)) corresponding to the protruding region (DSP1) and the recessed region (DSP2) of the data storage pattern (DSP).

In addition, the manufacturing system may form the vertical channel pattern (VCP) to have a protruding and recessed profile in the horizontal direction (for example, the first direction (D1) and the second direction (D2)) corresponding to the protruding region (DSP1) and the recessed region (DSP2) of the data storage pattern (DSP), and simultaneously, may form the protruding portion (VCP1) of the vertical channel pattern (VCP) such that the shape thereof is substantially the same as the shape of the protruding region (DSP1) of the data storage pattern (DSP). In this case, the thickness of the data storage pattern (DSP) may have the same value in the protruding region (DSP1) and the recessed region (DSP2).

However, the present invention is not limited thereto, and the manufacturing system may form the vertical channel pattern (VCP) to have a protruding and recessed profile in the horizontal direction (for example, the first direction (D1) and the second direction (D2)) corresponding to the protruding region (DSP1) and the recessed region (DSP2) of the data storage pattern (DSP), but may form the protruding portion (VCP1) of the vertical channel pattern (VCP) to have a tapered shape. In this case, the thickness of the data storage pattern (DSP) may have different values in the protruding region (DSP1) and the recessed region (DSP2).

Step (S560) is not limited to the manufacturing system forming the vertical channel pattern (VCP), and may include forming components included in the vertical channel structures (VS) described above (for example, the vertical filling pattern (FP), the conductive pad, and the like).

Steps (S550 and S560) may be performed as shown in FIG. 6E.

In step (S570), the manufacturing system may remove the sacrificial layers (SAC) as shown in FIG. 6F, and then form the gate electrodes (EL) in spaces from which the sacrificial layers (SAC) have been removed, as shown in FIG. 6G.

Although a method of manufacturing a 3D flash memory having a structure that does not include a back gate has been described above with reference to the drawings, a 3D flash memory having a structure including a back gate may also be manufactured based on the steps (S510 to S570) described above. In this case, the back gate may be formed to extend in the vertical direction by filling a conductive material into the internal space of the vertical channel pattern (VCP) in step (S560) in which the vertical channel pattern (VCP) is formed to extend.

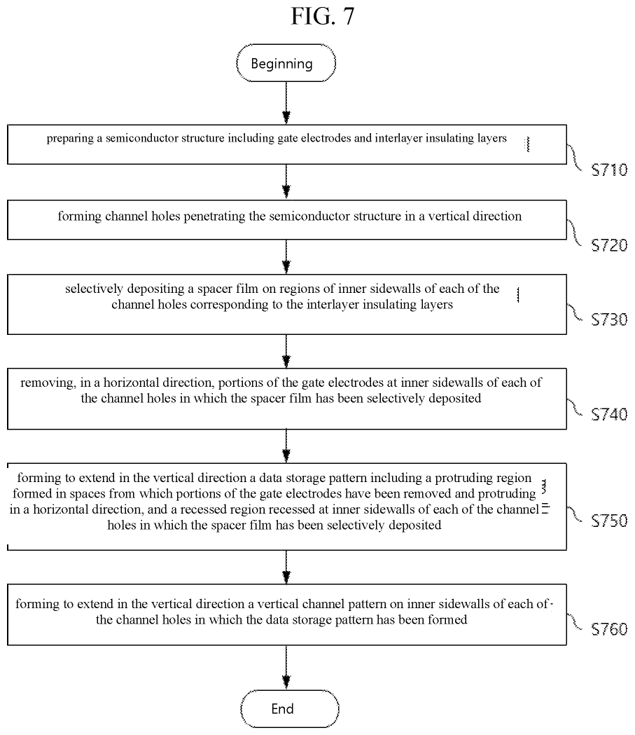

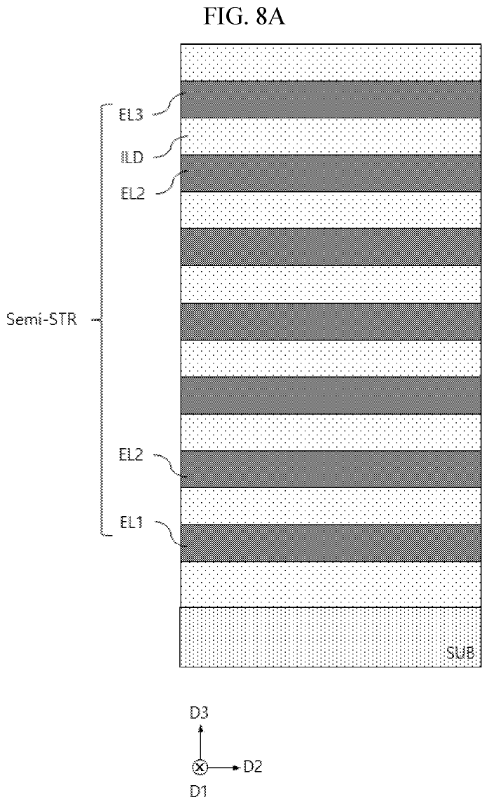

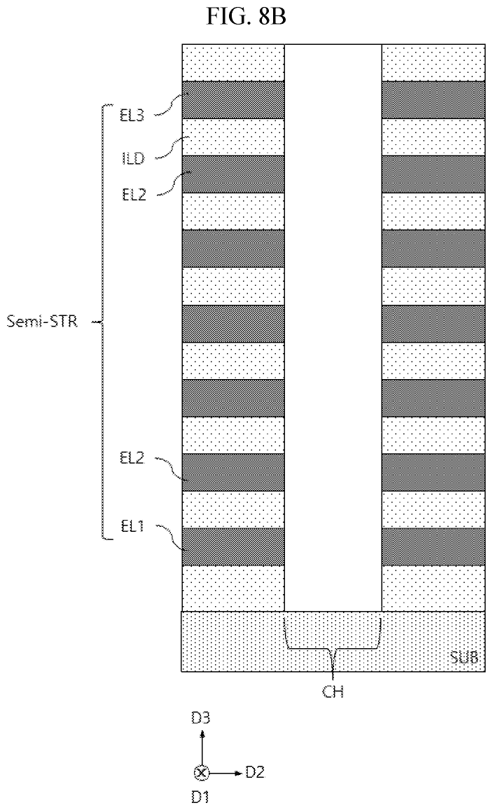

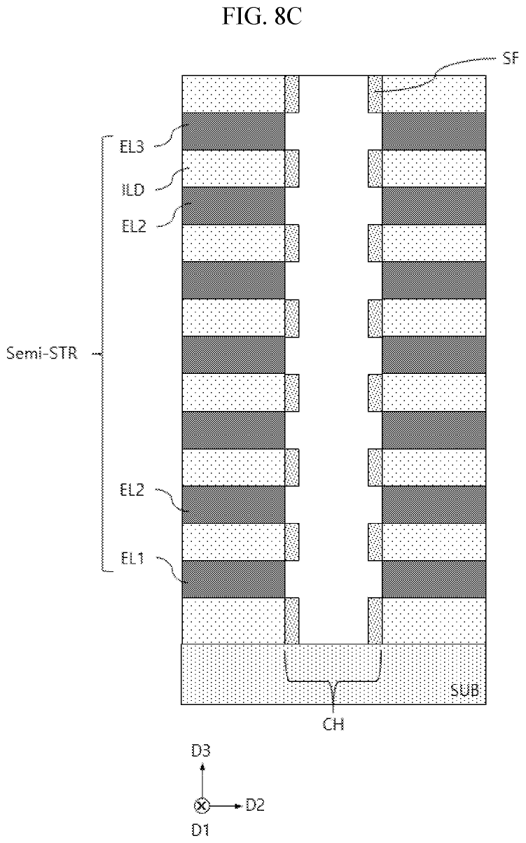

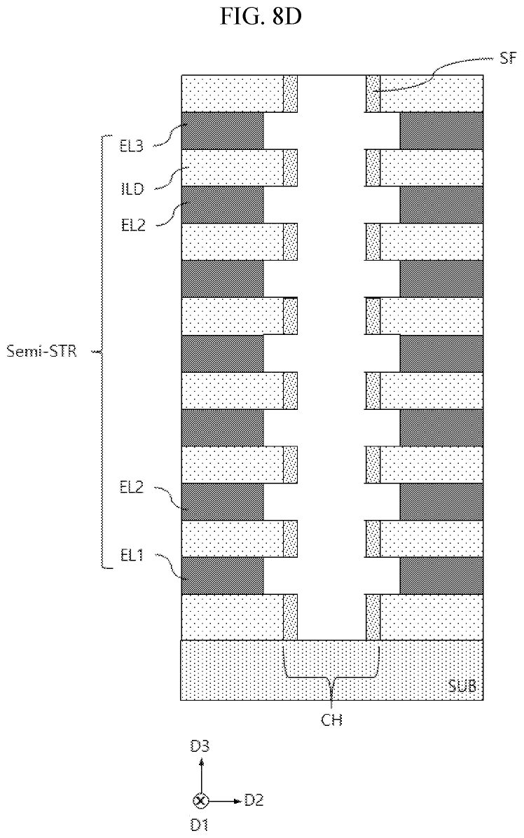

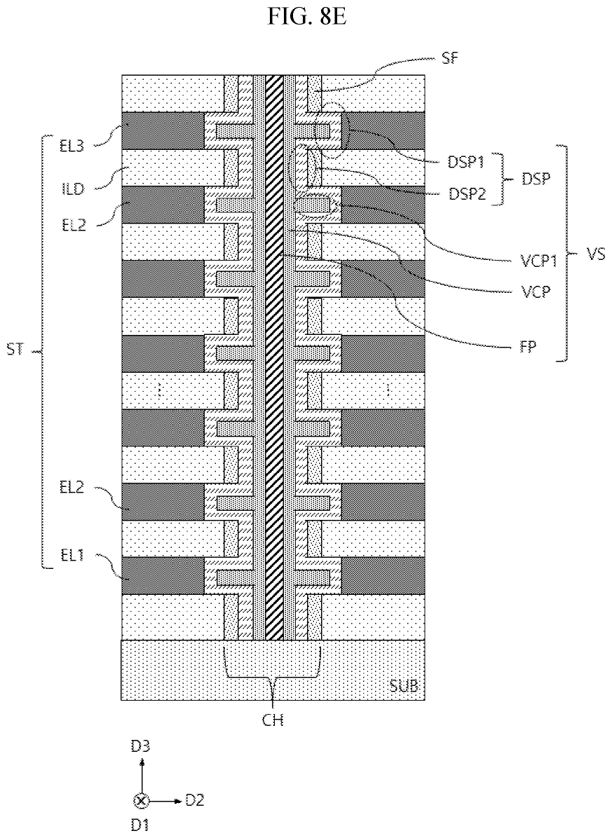

FIG. 7 is a flowchart illustrating a method for manufacturing a 3D flash memory according to another embodiment, and FIGS. 8A to 8E are cross-sectional views illustrating structures of a 3D flash memory for describing the method for manufacturing the 3D flash memory shown in FIG. 7.

The manufacturing method described below is for manufacturing a 3D flash memory having the structure shown in FIG. 1 based on a gate-first technique, and is assumed to be performed by an automated and mechanized manufacturing system.

However, the present invention is not limited thereto, and a 3D flash memory having the structure shown in FIG. 3 may also be manufactured using substantially the same sequence and method, with the only difference being the shape of the protruding portion (VCP1) of the vertical channel pattern (VCP). That is, the manufacturing method described below may be applied in the same manner to manufacture a 3D flash memory, not only when the protruding portion (VCP1) of the vertical channel pattern (VCP) is formed to have the same shape corresponding to the protruding region (DSP1) and the recessed region (DSP2) of the data storage pattern (DSP), but also when the protruding portion (VCP1) is formed in a tapered shape with a protruding width gradually decreasing along the vertical direction.

At this time, the protruding portion (VCP1) of the vertical channel pattern (VCP) may be selectively formed to have the same shape or a tapered shape by appropriately controlling process conditions for removing a portion of the data storage pattern (DSP) corresponding to the gate electrodes (EL) and process conditions for forming the vertical channel pattern (VCP) in spaces from which a portion of the data storage pattern (DSP) has been removed, so that a 3D flash memory including the vertical channel patterns (VCP) of various shapes may be manufactured in the same process flow.

Accordingly, the manufacturing method described below is not limited to a specific protruding shape of the vertical channel pattern (VCP), but may be commonly applied to the manufacture of a 3D flash memory including the vertical channel patterns (VCP) having various protruding shapes.

Referring to FIG. 7, in step (S710), the manufacturing system may prepare a semiconductor structure (SEMI-STR) including gate electrodes (EL) and interlayer insulating layers (ILD) that are formed to extend in a horizontal direction (for example, the first direction (D1) and the second direction (D2)) and are alternately stacked in the vertical direction, as shown in FIG. 8A.

In step (S720), the manufacturing system may form channel holes (CH) penetrating the semiconductor structure (SEMI-STR) in the vertical direction, as shown in FIG. 8B. Various etching schemes may be used in step (S720) of forming the channel holes (CH).

In step (S730), the manufacturing system, as shown in FIG. 8C, may selectively deposit a spacer film (SF) on regions of inner sidewalls of each of the channel holes (CH) corresponding to the interlayer insulating layers (ILD).

Selective deposition of the spacer film (SF) only in regions corresponding to the interlayer insulating layers (ILD) may be achieved by performing a deposition process in the channel holes (CH) after a process of activating surfaces of the interlayer insulating layers (ILD) exposed within the channel holes (CH) and deactivating surfaces of the gate electrodes (EL) exposed within the channel holes (CH).

Thus, step (S730) of selectively depositing the spacer film (SF) in regions corresponding to the interlayer insulating layers (ILD) is to allow the recessed region (DSP2) of the data storage pattern (DSP) to be disposed at a relatively recessed position in step (S750) described below.

In step (S740), the manufacturing system, as shown in FIG. 8D, may remove portions of the gate electrodes (EL) in the horizontal direction (for example, the first direction (D1) and the second direction (D2)) at inner sidewalls of each of the channel holes (CH) in which the spacer film (SF) has been selectively deposited.

Step (S740) of removing portions of the gate electrodes (EL) is to secure a space in which the protruding region (DSP1) of the data storage pattern (DSP) protruding from a region corresponding to the gate electrodes (EL) is to be formed.

In step (S750), the manufacturing system may form to extend in the vertical direction (for example, the third direction (D3)) the data storage pattern (DSP) including the protruding region (DSP1) formed in spaces from which portions of the gate electrodes (EL) have been removed and protruding in the horizontal direction (for example, the first direction (D1) and the second direction (D2)), and the recessed region (DSP2) recessed in the horizontal direction (for example, the first direction (D1) and the second direction (D2)) at inner sidewalls of each of the channel holes (CH) in which the spacer film (SF) has been selectively deposited.

Based on steps (S730 and S740), as the protruding region (DSP1) is formed in spaces from which portions of the gate electrodes (EL) have been removed in the horizontal direction (for example, the first direction (D1) and the second direction (D2)), and the recessed region (DSP2) is recessed by the spacer film (SF), step (S750) may be a step of forming the data storage pattern (DSP) having a protruding and recessed profile in the horizontal direction (for example, the first direction (D1) and the second direction (D2)).

Due to this structure, when a charge trapped in the protruding region (DSP1) at a position corresponding to the gate electrode (EL) transfers influence along the vertical direction (for example, the third direction (D3)) to a region of the data storage pattern (DSP) corresponding to another gate electrode (EL) adjacent thereto, the charge influence transfer path extends in a form including a path extending along the protruding region (DSP1) and the recessed region (DSP2), and thus may have a significantly increased length compared to a conventional structure in which the protruding region (DSP1) and the recessed region (DSP2) are not formed.

Thus, parasitic coupling or electrical interference that may occur between memory cells adjacent in the vertical direction may be effectively alleviated, and as a result, operation stability and data reliability of a memory device may be improved.

In step (S760), the manufacturing system may form the vertical channel pattern (VCP) extending in the vertical direction (for example, the third direction (D3)) on inner sidewalls of each of the channel holes (CH) in which the data storage pattern (DSP) is formed.

At this time, the manufacturing system may also form the vertical channel pattern (VCP) to have a protruding and recessed profile in the horizontal direction (for example, the first direction (D1) and the second direction (D2)) corresponding to the protruding region (DSP1) and the recessed region (DSP2) of the data storage pattern (DSP).

In addition, the manufacturing system may form the vertical channel pattern (VCP) to have a protruding and recessed profile in the horizontal direction (for example, the first direction (D1) and the second direction (D2)) corresponding to the protruding region (DSP1) and the recessed region (DSP2) of the data storage pattern (DSP), and may simultaneously form the protruding portion (VCP1) of the vertical channel pattern (VCP) such that the shape thereof is substantially the same as the shape of the protruding region (DSP1) of the data storage pattern (DSP). In this case, the thickness of the data storage pattern (DSP) may have the same value in the protruding region (DSP1) and the recessed region (DSP2).

However, without being limited thereto, the manufacturing system may form the vertical channel pattern (VCP) to have a protruding and recessed profile in the horizontal direction (for example, the first direction (D1) and the second direction (D2)) corresponding to the protruding region (DSP1) and the recessed region (DSP2) of the data storage pattern (DSP), but may form the protruding portion (VCP1) of the vertical channel pattern (VCP) to have a tapered shape. In this case, the thickness of the data storage pattern (DSP) may have different values in the protruding region (DSP1) and the recessed region (DSP2).

Step (S760) is not limited to the manufacturing system forming the vertical channel pattern (VCP), and may include forming components (for example, the vertical filling pattern (FP), the conductive pad, and the like) included in the above-described vertical channel structures (VS).

Steps (S750 and S760) may be performed as shown in FIG. 8E.

Although a method of manufacturing a 3D flash memory having a structure that does not include a back gate has been described with reference to the drawings above, a 3D flash memory having a structure including a back gate may also be manufactured based on the steps (S710 to S760) described above. In this case, the back gate may be formed to extend in the vertical direction by filling a conductive material into the internal space of the vertical channel pattern (VCP) in step (S760) of forming to extend the vertical channel pattern (VCP).

Although the embodiments have been described above with reference to specific embodiments and drawings, those skilled in the art may make various modifications and variations based on the above description. For example, even if the described techniques are performed in an order different from the described method, and/or components of the described systems, structures, apparatuses, circuits, and the like are combined or configured in a form different from the described method, or replaced or substituted by other components or equivalents, appropriate results may be achieved.

Therefore, other implementations, other embodiments, and equivalents to the claims also fall within the scope of the claims set forth below.

1. A 3D flash memory comprising:
interlayer insulating layers and gate electrodes extending in a horizontal direction and alternately stacked in a vertical direction; and
vertical channel structures extending in the vertical direction in channel holes penetrating the interlayer insulating layers and the gate electrodes, each of the vertical channel structures comprising a vertical channel pattern extending in the vertical direction, and a data storage pattern contacting an outer sidewall of the vertical channel pattern and extending in the vertical direction, the data storage pattern comprising a protruding region protruding in the horizontal direction corresponding to the gate electrodes and a recessed region recessed in the horizontal direction corresponding to the interlayer insulating layers.

2. The 3D flash memory of claim 1, wherein
the data storage pattern comprises the protruding region formed in spaces from which portions of the gate electrodes at inner sidewalls of each of the channel holes have been removed in the horizontal direction, and the recessed region recessed by a spacer film selectively deposited on inner sidewalls of the interlayer insulating layers in each of the channel holes, the data storage pattern having a protruding and recessed profile in the horizontal direction.

3. The 3D flash memory of claim 2, wherein
a horizontal distance from a central axis of the vertical channel pattern to the outer surface of the data storage pattern varies along the vertical direction depending on the protruding region and the recessed region.

4. The 3D flash memory of claim 2, wherein
the protruding region and the recessed region are alternately arranged along the vertical direction.

5. The 3D flash memory of claim 1, wherein
the vertical channel pattern has a protruding and recessed profile in the horizontal direction corresponding to the protruding region and the recessed region of the data storage pattern.

6. The 3D flash memory of claim 5, wherein
a protruding portion of the protruding and recessed profile of the vertical channel pattern has a tapered shape having a width decreasing in the horizontal direction.

7. The 3D flash memory of claim 1, wherein
the thickness of the data storage pattern is different between the protruding region and the recessed region.

8. A method for manufacturing a 3D flash memory, the method comprising:
providing a semiconductor structure comprising sacrificial layers and interlayer insulating layers extending in a horizontal direction and alternately stacked in a vertical direction;
forming channel holes penetrating the semiconductor structure in the vertical direction;
selectively depositing a spacer film on regions of inner sidewalls of each of the channel holes corresponding to the interlayer insulating layers;
removing, in the horizontal direction, portions of the sacrificial layers at inner sidewalls of each of the channel holes in which the spacer film has been selectively deposited;
forming a data storage pattern extending in the vertical direction, the data storage pattern comprising a protruding region formed in spaces from which the portions of the sacrificial layers have been removed and protruding in the horizontal direction, and a recessed region recessed in the horizontal direction at inner sidewalls of each of the channel holes in which the spacer film has been selectively deposited;
forming a vertical channel pattern extending in the vertical direction on inner sidewalls of each of the channel holes in which the data storage pattern has been formed; and
removing the sacrificial layers and forming gate electrodes in spaces from which the sacrificial layers have been removed.

9. The method of claim 8, wherein
forming the data storage pattern extending in the vertical direction comprises forming the data storage pattern having a protruding and recessed profile in the horizontal direction, wherein the protruding region is formed in spaces from which portions of the sacrificial layers have been removed in the horizontal direction, and the recessed region is recessed by the spacer film.

10. A method for manufacturing a 3D flash memory, the method comprising:
providing a semiconductor structure comprising gate electrodes and interlayer insulating layers extending in a horizontal direction and alternately stacked in a vertical direction;
forming channel holes penetrating the semiconductor structure in the vertical direction;
selectively depositing a spacer film on regions of inner sidewalls of each of the channel holes corresponding to the interlayer insulating layers;
removing, in the horizontal direction, portions of the gate electrodes at inner sidewalls of each of the channel holes in which the spacer film has been selectively deposited;
forming a data storage pattern extending in the vertical direction, the data storage pattern comprising a protruding region formed in spaces from which the portions of the gate electrodes have been removed and protruding in the horizontal direction, and a recessed region recessed in the horizontal direction at inner sidewalls of each of the channel holes in which the spacer film has been selectively deposited; and
forming a vertical channel pattern extending in the vertical direction on inner sidewalls of each of the channel holes in which the data storage pattern has been formed.

11. The method of claim 10, wherein
forming the data storage pattern extending in the vertical direction comprises forming the data storage pattern having a protruding and recessed profile in the horizontal direction, wherein the protruding region is formed in spaces from which portions of the gate electrodes have been removed in the horizontal direction, and the recessed region is recessed by the spacer film.

12. The method of claim 8 or 10, wherein
forming the vertical channel pattern extending in the vertical direction comprises forming the vertical channel pattern having a protruding and recessed profile in the horizontal direction corresponding to the protruding region and the recessed region of the data storage pattern.
